(19) United States
(12) Patent Application Publication
(10) Pub. No.: US 2025/0340490 A1
(43) Pub. Date: Nov. 6, 2025

(54) SILICON NITRIDE COMPOSITE MATERIAL AND PROBE-GUIDING PART

(71) Applicant: KROSAKIHARIMA CORPORATION, Fukuoka (JP)

(72) Inventors: Taiji MATANO, Fukuoka (JP); Toshio HAMASAKI, Fukuoka (JP); Yutaka SATO, Fukuoka (JP)

(73) Assignee: KROSAKIHARIMA CORPORATION, Fukuoka (JP)

(21) Appl. No.: 18/709,170

(22) PCT Filed: Oct. 6, 2022
(86) PCT No.: PCT/JP2022/037431

§ 371 Date: Oct. 7, 2024

(30) Foreign Application Priority Data
Nov. 15, 2021 (JP) 2021-185900

(51) Int. Cl. C04B 35/584; G01R 1/067

(52) U.S. Cl. CPC C04B 35/584; G01R 1/06705; C04B 2235/3206; C04B 2235/3217; C04B 2235/3225; C04B 2235/3248; C04B 2235/3418; C04B 2235/3873

(57) ABSTRACT

The present invention provides a silicon nitride composite material and a probe-guiding part, which stably have a coefficient of thermal expansion equivalent to a silicon wafer, and high strength. The silicon nitride composite material of the present invention contains: Si₃N₄ in an amount of 35% by mass to 70% by mass; ZrO₂ in an amount of 25% by mass to 60% by mass; and one or more selected from the group consisting of MgO, SiO₂, Al₂O₃, and Y₂O₃, in an amount of 0.5% by mass to less than 5% by mass, wherein a peak intensity ratio: Iβ/(Iα+Iβ), is 0.05 to 0.80, where Iα denotes the (210) plane peak intensity of αSi₃N₄, as measured by X-ray powder diffraction, and Iβ denotes the (210) plane peak intensity of βSi₃N₄, as measured by X-ray powder diffraction. The probe-guiding part of the present invention comprises a plate-shaped body using the above silicon nitride composite material, wherein the body has a plurality of through-holes and/or slits each for inserting the probe therethrough.

### TECHNICAL FIELD

The present invention relates to a silicon nitride composite material and a probe-guiding part.

### BACKGROUND ART

IC chips or LSI chips are provided for use by fabricating a large number of chips on a single silicon wafer and cutting the wafer into individual chips. In this process, checkup as to whether or not each chip is defective is performed using a probe card before the wafer is cut into individual chips. As disclosed in, e.g., Patent Document 1, the structure of the probe card comprises a probe, a substrate to which one end of the probe is attached, and a guide plate (probe-guiding part) for slidably guiding the probe, wherein the probe is inserted through a guide hole of the guide plate, so that a distal end of the probe is accurately brought into contact with a pad (electrode) of an IC or LSI chip formed on a silicon wafer. Then, an electrical signal is applied in this contact state, and an electrical signal output from the chip is analyzed to determine the presence or absence of a defect in the chip. This checkup is often performed at room temperature or in high-temperature environments (e.g. 80-150° C.). Thus, it is required for this type of probe card guide plate (probe-guiding part) to have a coefficient of thermal expansion similar to that of a silicon wafer in a temperature range from room temperature to about 200° C.

On the other hand, the probe-guiding part is also required to have a mechanical strength (bending strength) withstanding a probe load, and in recent years, there has been an increasing need for higher strength. Under these circumstances, Patent Document 2 discloses that combining ZrO₂, which is a high-expansion ceramic material, with Si₃N₄, which is a high-strength ceramic material, is effective for obtaining a ceramic material having a coefficient of thermal expansion nearly equal to that of a silicon wafer, and high strength.

### CITATION LIST

### [Patent Document]

Patent Document 1: JP 2003-215163A
Patent Document 2: WO 2019/093370

### SUMMARY OF INVENTION

### Technical Problem

The present inventors experimentally produced silicon nitride composite materials by combining ZrO₂ with Si₃N₄ under various conditions, in accordance with the disclosure of the Patent Document 2, and evaluated the thermal expansion property and strength property thereof. As a result, desired properties could not be sufficiently obtained depending on conditions for experimental production or the like.

Therefore, a technical problem to be solved by the present invention is to provide a silicon nitride composite material and a probe-guiding part, which stably have a coefficient of thermal expansion equivalent to that of a silicon wafer, and high strength.

### Solution to Technical Problem

As a result of various experiments and researches for solving the above technical problem, the present inventors have found that in order to allow a silicon nitride composite material produced by combining ZrO₂ with Si₃N₄ to stably have a coefficient of thermal expansion equivalent to that of a silicon wafer and high strength, it is important to control not only the content rate of each of a plurality components such as Si₃N₄ and ZrO₂ but also the microstructure of the silicon nitride composite material. The present inventors further have found that in the control of the microstructure of the silicon nitride composite material, it is important to set a peak intensity ratio: Iβ/(Iα+Iβ) to fall within a given range, where Iα denotes the (210) plane peak intensity of αSi₃N₄, as measured by X-ray powder diffraction, and Iβ denotes the (210) plane peak intensity of βSi₃N₄, as measured by X-ray powder diffraction, although the details will be described later.

Specifically, according to a first aspect of the present invention, there is provided a silicon nitride composite material containing: Si₃N₄ in an amount of 35% by mass to 70% by mass; ZrO₂ in an amount of 25% by mass to 60% by mass; and one or more selected from the group consisting of MgO, SiO₂, Al₂O₃, and Y₂O₃, in an amount of 0.5% by mass to less than 5% by mass, wherein a peak intensity ratio: Iβ/(Iα+Iβ), is 0.05 to 0.80, where Iα denotes the (210) plane peak intensity of αSi₃N₄, as measured by X-ray powder diffraction, and Iβ denotes the (210) plane peak intensity of βSi₃N₄, as measured by X-ray powder diffraction.

According to a second aspect of the present invention, there is provided a probe-guiding part for guiding a probe of a probe card, comprising a plate-shaped body using the silicon nitride composite material according to the first aspect of the present invention, wherein the body has a plurality of through-holes and/or slits each for inserting the probe therethrough.

### Advantageous Effects of Invention

The present invention can provide a silicon nitride composite material and a probe-guiding part, which stably have a coefficient of thermal expansion equivalent to that of a silicon wafer, and high strength.

### BRIEF DESCRIPTION OF DRAWINGS

FIG. 1 is X-ray powder diffraction intensity data of a silicon nitride composite material in one example of the present invention (Inventive Example 4 in Table 1).

FIG. 2 is an SEM photograph of a cut surface of a silicon nitride composite material in one example of the present invention (Inventive Example 8 in Table 1).

FIG. 3 is a SEM photograph of a cut surface of a silicon nitride composite material in one comparative example (Comparative Example 9 in Table 1).

### DESCRIPTION OF EMBODIMENTS

A silicon nitride composite material of the present invention is produced by combining high-expansion ZrO₂ with high-strength Si₃N₄, wherein the silicon nitride composite material contains, as primary components, Si₃N₄ in an amount of 35% by mass to 70% by mass, and ZrO₂ in an amount of 25% by mass to 60% by mass.

If the content rate of Si₃N₄ is less than 35% by mass, it becomes difficult to obtain high strength. On the other hand, if the content rate of Si₃N₄ is greater than 70% by mass, it becomes difficult to obtain a coefficient of thermal expansion nearly equal to that of a silicon wafer. Preferably, the content rate of Si₃N₄ is 50% by mass to 60% by mass.

Further, if the content rate of ZrO₂ is less than 25%, it becomes impossible to obtain a high coefficient of thermal expansion, leading to difficulty in obtaining a coefficient of thermal expansion nearly equal to that of a silicon wafer. If the content rate of ZrO₂ is greater than 60% by mass, the coefficient of thermal expansion becomes excessively high, leading to difficulty in obtaining a coefficient of thermal expansion nearly equal to that of a silicon wafer. Preferably, the content rate of ZrO₂ is 35% by mass to 45% by mass.

Further, a total content rate of Si₃N₄ and ZrO₂ is preferably 90% by mass to 99.5% by mass, more preferably 90% by mass to 98% by mass.

One feature of the silicon nitride composite material of the present invention is that when the (210) plane peak intensity of αSi₃N₄, as measured by X-ray powder diffraction, is denoted by Iα, and the (210) plane peak intensity of βSi₃N₄, as measured by X-ray powder diffraction, is denoted by Iβ, a peak intensity ratio: Iβ/(Iα+Iβ) (hereinafter referred to simply as “peak intensity ratio”) is 0.05 to 0.80. When the peak intensity ratio is greater than 0.8, the coefficient of thermal expansion is not increased to a given value even if the content rate of ZrO₂ falls within the above specified range. On the other hand, when the peak intensity ratio is less than 0.05, the amount of βSi₃N₄ having higher strength than αSi₃N₄ is excessively small, and thus mechanical strength is undesirably reduced. The reason will be described below.

In the silicon nitride composite material, the control of thermal expansion properties is made possible by controlling not only the content rate of each component thereof, such as Si₃N₄ or ZrO₂, but also the microstructure thereof. High strength inherent in silicon nitride also depends on the microstructure. The present inventors have found that the peak intensity ratio measured by X-ray powder diffraction of silicon nitride is important for accurately controlling the microstructure.

As a starting material for the silicon nitride composite material, basically, an αSi₃N₄ raw material is used as silicon nitride, and a ZrO₂ raw material stabilized by Y₂O₃ or the like is used as zirconia. Then, in the same manner as a conventional ceramics production method, a molded body of a mixture of the raw materials is sintered. In this sintering process, ceramic particles undergo grain growth. The same is true for both the silicon nitride and zirconia in this respect. In this process, the crystal structure of the silicon nitride also transitions from αSi₃N₄ to βSi₃N₄. The βSi₃N₄ is a needle-like crystal having a high aspect ratio.

When zirconia having a high coefficient of thermal expansion and silicon nitride having a low coefficient of thermal expansion become a composite microstructure through the sintering process, the composite microstructure will exhibit different behaviors in the next cooling process depending on the size of the crystal grains thereof. In a case where crystal grains of both the materials have grown in the sintering process, the silicon nitride undergoes a phase transition to βSi₃N₄ in a large amount, and the grain sizes of the αSi₃N₄ and zirconia become larger. However, the amount of αSi₃N₄ is reduced by the amount of the transition from α-phase to β-phase. That is, a part of the αSi₃N₄ is incorporated into the βSi₃N₄. In this case, since αSi₃N₄ present between zirconia grains decreases, and the amount of zirconia grains each coupled to adjacent zirconia grains increases relatively. The sintering is completed in this state, and then each grain will gradually shrink in the cooling process. Zirconia has a greater shrinkage amount than silicon nitride due to its material properties. In addition, along with the shrinkage, a tensile stress acts on the coupled zirconia grains, leading to a state in which cracks are formed between the zirconia and nitride silicon or between the zirconia and zirconia, and a clearance occurs therebetween.

When heating a silicon nitride composite material obtained under this condition, both the silicon nitride and zirconia will gradually expand, but the expansion of the zirconia is absorbed by the above-mentioned cracks, and does not contribute to an increase in thermal expansion as a whole. Thus, the coefficient of thermal expansion of the zirconia will remain at a value equal to or less than the theoretical coefficient of thermal expansion.

Conversely, in a case where crystal grains of both the materials have not grown in the sintering process, the silicon nitride undergoes a phase transition to βSi₃N₄ in a small amount, and is in a state in which a certain amount of βSi₃N₄ exists in a matrix where zirconia and αSi₃N₄ having a grain size nearly equal to that of the zirconia are intertwined with each other.

When heating a silicon nitride composite material obtained under this condition, both the silicon nitride and zirconia are expanded, and the silicon nitride composite material has a coefficient of thermal expansion greater than that of a material of silicon nitride only.

The present inventors have found that the peak intensity ratio is preferably set, as a control parameter of the microstructure of such a silicon nitride composite material, to fall within the range of 0.05 to 0.80.

When the peak intensity ratio is greater than 0.80, the amount of βSi₃N₄ is excessively larger, and the amount of αSi₃N₄ is excessively small, i.e., αSi₃N₄ exists, but the amount thereof is excessively small due to a phase transition of a large part of αSi₃N₄ to βSi₃N₄. Thus, the zirconia undergoes grain growth to form a coupled microstructure, so that an increase in coefficient of thermal expansion is small. This makes it difficult to obtain a coefficient of thermal expansion nearly equal to that of a silicon wafer.

The peak intensity ratio also has an influence as a condition for maintaining high strength of a silicon nitride ceramic material. Specifically, the strength becomes higher as the amount of βSi₃N₄ which is a needle-like crystal formed through 3-phase transition of αSi₃N₄ becomes larger. Thus, when the peak intensity ratio is less than 0.05, it means that the amount of βSi₃N₄, which is a needle-like crystal formed through 3-phase transition of αSi₃N₄, is excessively small, so that it becomes difficult to maintain high strength of the silicon nitride ceramic material.

Preferably, the peak intensity ratio is 0.25 to 0.65.

Here, since silicon nitride is a material having a strong covalent property, sintering of silicon nitride by itself is impossible. For this reason, it is common to sinter silicon nitride via a liquid phase formed by adding thereto an oxide acting as a sintering aid which easily forms a liquid phase during sintering. As such an oxide, the present invention uses one or more selected from the group consisting of MgO, SiO₂, Al₂O₃, and Y₂O₃, each of which only needs to be added in a relatively small amount. SiO₂ as an oxide film on the surface of silicon nitride particles also becomes an SiO₂ source, but silicon oxide serving as an SiO₂ source may be added separately.

After the sintering, the liquid phase basically becomes a non-crystalline phase, but a part of the liquid phase is crystallized in some cases. Further, there is a possibility that zirconia is partially dissolved in the liquid phase. After the sintering, these phases are present around or in the vicinity of the grain boundaries of the silicon nitride grains. The content rate of the above-mentioned oxide component is set to fall within the range of 0.5% by mass to less than 5% by mass in total. If the content ratio is less than 0.5 mass %, it is impossible to obtain a liquid phase enough to allow the silicon nitride to be sintered to control the crystal phase of the silicon nitride. On the other hand, if the content ratio is equal to or greater than 5% by mass, zirconia particles become more likely to be mutually sintered, leading to the state in which cracks are formed between the zirconia and nitride silicon or between the zirconia and zirconia is in a state in which a clearance is generated between the zirconia-nitride silicon or the zirconia-zirconia, for the above-mentioned reason, so that expansion of the zirconia is absorbed by the cracks, and does not contribute to an increase in thermal expansion as a whole. Moreover, there is a possibility that another oxide is generated, and it becomes impossible to maintain high strength inherent in silicon nitride.

Preferably, the content rate of the oxide component is 1% by mass to 3% by mass in total.

As mentioned above, the silicon nitride composite material of the present invention is obtained by preparing a starting material, basically using an αSi₃N₄ raw material as silicon nitride, and a ZrO₂ raw material stabilized by Y₂O₃ or the like, as zirconia, and sintering a molded body of a mixture of the raw materials in the same manner as a conventional ceramics production process, but a βSi₃N₄ raw material may be use if it is a small amount. As the ZrO₂ raw material stabilized by Y₂O₃ or the like, it is preferable to use a stabilized ZrO₂ which is a cubic crystal. Alternatively, a partially-stabilized ZrO₂ raw material which is a tetragonal crystal may be used. The ZrO₂ raw material stabilized by Y₂O₃ or the like comprises a stabilizing component such as Y₂ O₃. In the silicon nitride composite material of the present invention, the content rate of the stabilizing component such as Y₂ O₃ shall be included in the content ratio of ZrO₂. In other words, the content rate of the stabilizing component such as Y₂ O₃, which is comprised in the ZrO₂ raw material, shall not be included in the content rate of the above-mentioned oxide component acting as the sintering aid.

In the silicon nitride composite material of the present invention, the content rate of each of the above-mentioned components can be basically identified by ICP (Inductively Coupled Plasma) emission spectrochemical analysis. In the ICP emission spectrochemical analysis, the stabilizing component such as Y₂O₃ comprised in the ZrO₂ raw material cannot be distinguished from the above-mentioned oxide component acting as the sintering aid. However, since the content rate of the stabilizing component such as Y₂O₃ comprised in the ZrO₂ raw material can be identified preliminarily, the content rate of the oxide component acting as the sintering aid can be identified by subtracting the content ratio of the stabilizing component such as Y₂ O₃ comprised in the ZrO₂ raw material from the value identified by the ICP emission spectrochemical analysis.

Preferably, as components other than the above-mentioned components, the silicon nitride composite material of the present invention may contain Si₂N₂₀: silicon oxynitride, Y₃Al₅O₁₂: YAG (yttrium·aluminum·garnet), and/or R₂SiO₄ (R is Mg, Fe, Mn, Ca, etc.): forsterite, wherein the content thereof is preferably 9% by mass or less, in total.

One feature of the silicon nitride composite material of the present invention is that the peak intensity ratio is 0.05 to 0.80, as mentioned above. This peak intensity ratio can be controlled by sintering temperature. Specifically, the peak intensity ratio can be set to fall within the range of 0.05 to 0.80 by setting the sintering temperature to fall within the range of 1500° C. to 1670° C., as shown in the after-mentioned Examples.

By setting the content rate of each component and the peak intensity ratio to fall within given ranges, respectively, in the above manner, it becomes possible to obtain a silicon nitride composite material stably having a coefficient of thermal expansion equivalent to that of a silicon wafer and high strength. Specifically, it becomes possible to stably obtain a thermal expansion property that the coefficient of thermal expansion at a temperature of room temperature to 200° C. is 3×10⁻⁶/° C. to 6×10⁻⁶/° C., and a strength property that the bending strength is 400 MPa or more, as shown in the after-mentioned Examples.

The silicon nitride composite material of the present invention is suitably used as a body of a probe-guiding part for guiding a probe of a probe card. More specifically, the probe-guiding part of the present invention comprises a plate-shaped body using the silicon nitride composite material of the present invention, wherein the body has a plurality of through-holes and/or slits each for inserting the probe therethrough.

As an application which requires performance similar to that of the probe-guiding part for guiding a probe of a probe card is required, the silicon nitride composite material of the present invention can also be used in an inspection socket such as a package inspection socket.

### EXAMPLES

In order to confirm an advantageous effect of the present invention, an α-Si₃N₄ powder, a stabilized ZrO₂ powder, and one or more types of oxide powders selected from MgO, Y₂O₃, Al₂O₃ and SiO₂, whose mixing ratio varies, were mixed together with water, a dispersant, a molding aid and ceramic balls, in a ball mill, and the obtained slurry was sprayed and dried by a spray drier to form a granulated powder. The granulated powder was pressed at a pressure of 140 MPa into a molded body of □ 4 0×t 30 mm, and then the molded body was subjected to degreasing treatment to remove the molding aid, etc. Then, the degreased body was set in a graphite die, and subjected to hot press sintering at a temperature of 1450° C. to 1700° C. for 2 hours, while applying a pressure of 30 MPa in a nitrogen atmosphere, to obtain a test material having a size of length 40 mm×width 40 mm×thickness 15 mm. Then, a test piece was taken from the obtained test material, and subjected to evaluations of the peak intensity ratio, the coefficient of thermal expansion, and the bending strength. Then, a comprehensive evaluation was performed from these evaluation results.

Table 1 shows the composition and evaluation result of each silicon nitride composite material in Inventive Examples and Comparative Examples. In Table 1, “other components”, means Si₂N₂O: silicon oxynitride, Y₃Al₅O₁₂: YAG (yttrium·aluminum·garnet), and/or R₂SiO₄ (R is Mg, Fe, Mn, Ca, etc.): forsterite, as mentioned above.

TABLE 1

| | Inven- | Inven- | Inven- | Inven- | Inven- | Inven- | Inven- | Inven- | Inven- | Inven- | Inven- | Inven- |
|---|---|---|---|---|---|---|---|---|---|---|---|---|
| | tive | tive | tive | tive | tive | tive | tive | tive | tive | tive | tive | tive |
| | Exam- | Exam- | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 9 | ple 10 | ple 11 | ple 12 |
| Si [symbol] N [symbol] | [symbol] | [symbol] | [symbol] | [symbol] | [symbol] | [symbol] | [symbol] | [symbol] | [symbol] | [symbol] | [symbol] | [symbol] |
| ZrO [symbol] | [symbol] | [symbol] | [symbol] | [symbol] | [symbol] | [symbol] | [symbol] | [symbol] | [symbol] | [symbol] | [symbol] | [symbol] |
| MgO | 1 | 1 | [symbol] | [symbol] | [symbol] | [symbol] | 1 | [symbol] | | 1 | | 1 |
| SiO [symbol] | | | | | | | | | 1 | | | 1 |
| Al [symbol] O [symbol] | | | | | | | | | | 1 | | |
| Y [symbol] O [symbol] | | | | | | | | | | [symbol] | 1 | |
| Other | 1 | 1 | [symbol] | [symbol] | [symbol] | [symbol] | [symbol] | [symbol] | [symbol] | [symbol] | 1 | 1 |
| components | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] |
| Peak [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] |

| | Compar- | Compar- | Compar- | Compar- | Compar- | Compar- | Compar- | Compar- | Compar- | Compar- |
|---|---|---|---|---|---|---|---|---|---|---|
| | ative | ative | ative | ative | ative | ative | ative | ative | ative | ative |
| | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 9 | ple 10 |
| Si [symbol] N [symbol] | [symbol] | [symbol] | [symbol] | [symbol] | [symbol] | [symbol] | [symbol] | [symbol] | [symbol] | [symbol] |
| ZrO [symbol] | [symbol] | [symbol] | [symbol] | [symbol] | [symbol] | [symbol] | [symbol] | [symbol] | [symbol] | [symbol] |
| MgO | 1 | 1 | 1 | 1 | | 10 | 10 | 1 | 1 | 1 |
| SiO [symbol] | | | | | | | | | | |
| Al [symbol] O [symbol] | | | | | | | | | | |
| Y [symbol] O [symbol] | | | | | | | | | | |
| Other | [symbol] | 1 | [symbol] | 1 | 1 | [symbol] | [symbol] | 1 | 1 | 1 |
| components | | | | | | | | | | |
| | [symbol] | [symbol] | [symbol] | [symbol] | [symbol] | [symbol] | [symbol] | [symbol] | [symbol] | [symbol] |
| Peak [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| | [symbol] | [symbol] | [symbol] | [symbol] | [symbol] | [symbol] | [symbol] | [symbol] | [symbol] | [symbol] |

[symbol]

indicates data missing or illegible when filed

The evaluations of the peak intensity ratio, the coefficient of thermal expansion, the bending strength, and the comprehensive evaluation were performed in the following manner.

### <Peak Intensity Ratio>

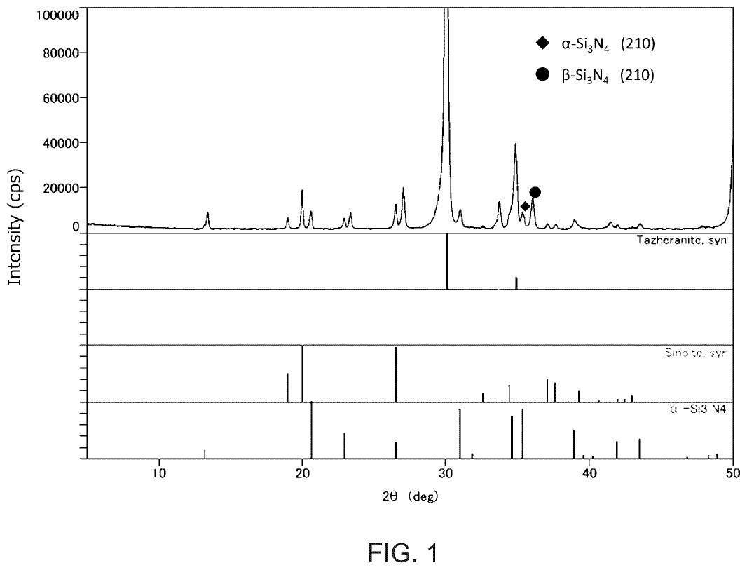

FIG. 1 shows X-ray powder diffraction intensity data of Inventive Example 4 in Table 1 as an example of X-ray powder diffraction. Based on this X-ray powder diffraction intensity data, the (210) plane peak intensity: Iα, of αSi₃N₄, and the (210) plane peak intensity: Iβ, of βSi₃N₄, were obtained, and then the peak intensity ratio: Iβ/(Iα+Iβ) was obtained.

### <Coefficient of Thermal Expansion>

With respect to the test piece in each Example, the coefficient of thermal expansion at a temperature of room temperature to 200° C. was obtained according to JIS R1618.

With regard to evaluation of the coefficient of thermal expansion (unit: 10⁻⁶/° C.), a test piece having a coefficient of thermal expansion of 3.5 to 5 was evaluated as ⊚ (excellent), and a test piece having a coefficient of thermal expansion of 3 to less than 3.5, or of greater than 5 to less than 6, was evaluated as ∘ (Good). Further, a test piece having a coefficient of thermal expansion of less than 3 was evaluated as x (low) (NG), and a test piece having a coefficient of thermal expansion of greater than 6 was evaluated as x (high) (NG).

### <Bending Strength>

With respect to the test piece in each Example, a four-point bending strength was obtained according to JIS R1601. With regard to evaluation of the bending strength (unit: MPa), a test piece having a bending strength of 600 or more was evaluated as ⊚ (excellent), and a test piece having a bending strength of 400 to less than 600 was evaluated as ∘ (Good). Further, a test piece having a bending strength of less than 400 was evaluated as x (NG).

### <Comprehensive Evaluation>

A test piece in which both the evaluations of the coefficient of thermal expansion and the bending strength were ⊚ (excellent) was comprehensively evaluated as ⊚ (excellent), and a test piece in which at least one of the two evaluations was ∘ (Good), and there is no x (NG) evaluation was comprehensively evaluated as ∘ (Good). Further, a test piece in which at least one of the two the evaluations was x (NG) was comprehensively evaluated as x (NG).

In Table 1, Invective Examples 1 to 12 each of whose composition (content rate of each component) and peak intensity ratio fall within the respective ranges of the present invention were comprehensively evaluated as ⊚ (excellent) or ∘ (Good), i.e., obtained good results. Among them, Inventive Examples 7 to 12 each of whose composition and peak intensity ratio fall within the respective preferred ranges were comprehensively evaluated as ⊚ (excellent), i.e., obtained particularly good results.

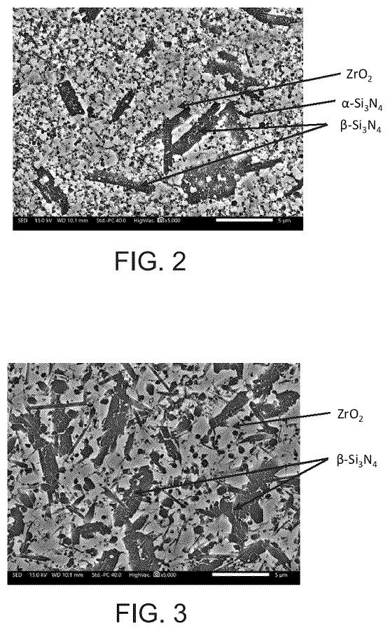

FIG. 2 is a SEM photograph of a cut surface of the silicon nitride composite material in Inventive Example 8. FIG. 2 shows that βSi₃N₄, which is a needle-like crystal, is present in an anisotropic manner in a matrix where zirconia and αSi₃N₄ having a grain size nearly equal to that of the zirconia are intertwined with each other.

In Table 1, Comparative Example 1 is an example in which the content rate of Si₃N₄ and the peak intensity ratio are excessively low. The evaluation of the bending strength was x (NG). Further, in Comparative Example 1 where the content rate of ZrO₂ is relatively high, the evaluation of the coefficient of thermal expansion was “x (high)”.

On the other hand, Comparative Example 2 is an example in which the content rate of Si₃N₄ and the peak intensity ratio are excessively high. The evaluation of the coefficient of thermal expansion was “x (low)”.

Comparative Example 3 is an example in which the content rate of ZrO₂ is excessively low. The evaluation of the coefficient of thermal expansion was “x (low)”. Comparative Example 4 is an example in which the content rate of ZrO₂ is excessively high. The evaluation of the coefficient of thermal expansion was “x (high)”.

Comparative Example 5 is an example in which no oxide component (MgO component) is contained, and the peak intensity ratio is excessively low. The evaluation of the bending strength was x (NG).

Comparative Example 6 is an example in which the content rate of the oxide component (MgO component) is excessively high. The evaluation of the bending strength was also x (NG).

Comparative Example 7 is an example in which the content rate of the oxide component (MgO component) and the peak intensity ratio are excessively high. The evaluation of the bending strength was x (NG), and the evaluation of the coefficient of thermal expansion was “x (low)”.

Comparative Examples 8 and 9 are examples where the peak intensity ratio is excessively high. In both of Comparative Examples 8 and 9, the evaluation of coefficient of thermal expansions was “x (low)”. Comparative Example 10 is an example in which the peak intensity ratio is excessively low. The evaluation of the bending strength was x (NG).

FIG. 3 is a SEM photograph of a cut surface of the silicon nitride composite material in Comparative Example 9. FIG. 3 shows that almost all of αSi₃N₄ has transitioned to βSi₃N₄ and has undergone grain growth together with ZrO₂.

1. A silicon nitride composite material containing:
Si₃N₄ in an amount of 35% by mass to 70% by mass;
ZrO₂ in an amount of 25% by mass to 60% by mass; and
one or more selected from the group consisting of MgO, SiO₂, Al₂O₃, and Y₂O₃, in an amount of 0.5% by mass to less than 5% by mass,
wherein a peak intensity ratio: Iβ/(Iα+Iβ), is 0.05 to 0.80, where Iα denotes the (210) plane peak intensity of αSi₃N₄, as measured by X-ray powder diffraction, and Iβ denotes the (210) plane peak intensity of βSi₃N₄, as measured by X-ray powder diffraction.

2. A probe-guiding part for guiding a probe of a probe card, comprising a plate-shaped body using the silicon nitride composite material as claimed in claim 1, wherein the body has a plurality of through-holes and/or slits each for inserting the probe therethrough.
